(19) United States
(12) Patent Application Publication
(10) Pub. No.: US 2025/0374592 A1
(43) Pub. Date: Dec. 4, 2025

(54) LAYOUT AND MODELING FOR LDMOS WITH BIASED FIELD PLATE

(71) Applicant: Texas Instruments Incorporated, Dallas, TX (US)

(72) Inventors: Henry Edwards, Garland, TX (US); Ali Saadat, Santa Clara, CA (US); Vijay Reddy, Plano, TX (US); Xiaochuan Bi, Saratoga, CA (US); Vijay Krishnamurthy, Sunnyvale, CA (US); Ming-Yeh Chuang, McKinney, TX (US); Timothy A. Rost, Plano, TX (US)

(21) Appl. No.: 18/731,171

(22) Filed: May 31, 2024

(51) Int. Cl. H01L 29/78; G06F 30/398; H01L 29/06; H01L 29/08; H01L 29/10; H01L 29/40

(52) U.S. Cl. CPC H10D 30/65; G06F 30/398; H10D 62/115; H10D 62/156; H10D 62/393; H10D 64/111

(57) ABSTRACT

A method of fabricating a semiconductor device includes creating a device model of a drain extended transistor with a biased field plate, simulating performance of the drain extended transistor using the device model, adjusting the device model based on the simulation to create an adjusted device model to improve a figure of merit, and creating a circuit model of the drain extended transistor based on the adjusted device model. A semiconductor device includes a drain extended transistor having a field relief dielectric layer over a drain drift region, and a biased field plate over the field relief dielectric layer where a position and bias voltage of the field plate are determined by adjusting a device model of the drain extended transistor based on simulated performance of the drain extended transistor using the device model.

### BACKGROUND

Drain extended transistors are used in high voltage applications that require high breakdown voltage ratings and efficient operation, such as a low side switch in a switching power supply to provide low drain-source resistance (RDSON) during the on-state, along with the ability to block or withstand high off-state voltages between the drain and the source or gate. The extended drain architecture has a lightly doped drift region that allows carrier depletion under drain reverse bias so that the drain can block current flow during high voltage operation. The polysilicon gate can be extended across a field relief oxide above the drift region to improve drift region charge balance. However, this approach leaves a nonuniform electric field with peaks in the drift region during off-state operation, such as a peak under the end of the polysilicon field plate. The non-uniform electric field reduces the breakdown voltage from an ideal value and can lead to sub-optimal breakdown voltage performance that can only be addressed by increasing the lateral drift region length to accommodate a required drain blocking voltage in the off-state within the limits of semiconductor breakdown strength. Increasing the drift region length to help voltage breakdown performance inhibits efforts to reduce circuit area and increases the on-state drain-source resistance (RDSON) of the transistor as the carriers have more material to travel through.

### SUMMARY

In one aspect, a method includes creating a device model of a drain extended transistor with a biased field plate, simulating performance of the drain extended transistor using the device model, adjusting the device model based on the simulation to create an adjusted device model to improve a figure of merit, and creating a circuit model of the drain extended transistor based on the adjusted device model.

A semiconductor device includes a drain extended transistor having a semiconductor layer over a semiconductor substrate, the semiconductor layer including a body region having a first conductivity type and a drain drift region having a second, opposite, conductivity type, a gate dielectric layer over the body region and extending over a junction between the body region and the drain drift region, a gate electrode over the gate dielectric layer, a drain region having the second conductivity type in the drain drift region, the drain region having a dopant density greater than a dopant density of the drain drift region, a field relief dielectric layer over the drain drift region, the field relief dielectric layer extending from the gate dielectric layer toward the drain region and having a thickness greater than the gate dielectric layer, and a field plate located over the field relief dielectric layer and between the gate electrode and the drain region, wherein a position and bias voltage of the field plate are determined by adjusting a device model of the drain extended transistor based on simulated performance of the drain extended transistor using the device model.

### BRIEF DESCRIPTION OF THE DRAWINGS

FIG. 1 is a partial sectional side elevation view of a semiconductor device including a drain extended transistor with a biased field plate taken along line 1-1 in FIG. 1A.

FIG. 1A is a partial top plan view of the semiconductor device of FIG. 1.

FIG. 2 is a flow diagram of a method of fabricating a semiconductor device.

FIG. 2A is a partial sectional side elevation view and schematic representation of an extended drain transistor model with modeled drain-to-field plate capacitor and a modeled drain-to-field plate resistor.

FIG. 2B is a graph with curves showing non-linear drain-to-field plate capacitor modeling with modulation based on the drain and source voltages in one implementation of the extended drain transistor model of FIG. 2A.

FIG. 2C is a graph with curves showing non-linear drain-to-field plate resistor modeling with modulation based on the field plate bias voltage in one implementation of the extended drain transistor model of FIG. 2A.

FIG. 3 is a graph of off-state breakdown voltage operation of a 40 V transistor with a field plate biased to 20 V including simulated net carriers, equipotential lines and electric field magnitude with a more uniform drift region charge balance with a small half pitch dimension to achieve a given breakdown voltage.

FIG. 3A is a graph of on-state breakdown voltage operation of the 40 V transistor of FIG. 3 with the field plate biased to 20 V including simulated net carrier amounts, electron quasi Fermi levels and current flow showing the field plate accumulating the transistor channel and reducing the on-state drain-source resistance below what could be achieved without the biased field plate with the same transistor half pitch dimension.

FIG. 4 is a graph of electric field strength as a function of lateral position along a transistor drift region for a reference transistor with no field plate and transistors with different voltage ratings and a field plate biased at approximately half the rated voltage.

FIG. 5 is a breakdown voltage sweep graph of off-state transistor drain current as a function of drain-source voltage for the reference transistor with no field plate and the transistors with different voltage ratings and a field plate biased at approximately half the rated voltage.

FIG. 6 is a linear drain current sweep graph of on-state transistor drain current as a function of gate-source voltage for the reference transistor with no field plate and the transistors with different voltage ratings and a field plate biased at approximately half the rated voltage showing low RDSON and high linear drain current facilitated by drift region accumulation by field plate bias.

FIG. 7 is a graph of linear drain current as a function of field plate bias voltage for the reference transistor with no field plate and the transistors with different voltage ratings and a field plate.

FIG. 8 is a partial sectional side elevation view of an extended drain transistor model with a graph of off-state drift region voltage as a function of lateral distance from the source to the drain and a graph of voltage as a function of vertical depth.

FIGS. 9, 9A, 9B, and 9C are graphs of field plate bias voltage as a function of lateral distance from the source to the drain with an ideal linear modeled curve and a simulated single biased field plate lateral position and width for the transistors with different voltage ratings and a field relief oxide.

FIGS. 10, 10A, 10B, and 10C are graphs of field plate bias voltage as a function of lateral distance from the source to the drain with an ideal linear modeled curve and simulated single and multiple biased field plates.

FIG. 11 is a partial sectional side elevation view of another semiconductor device including a drain extended transistor with three biased field plates.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”. Unless otherwise stated, “about,” “approximately,” or “substantially” preceding a value means+/−10 percent of the stated value.

One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for case of description in connection with a particular drawing, where such are not to be construed as limiting with respect to the claims. Various disclosed structures and methods of the present disclosure may be beneficially applied to manufactured electronic apparatus such as an integrated circuit. While such examples may be expected to provide various improvements, no particular result is a requirement of the present disclosure unless explicitly recited in a particular claim.

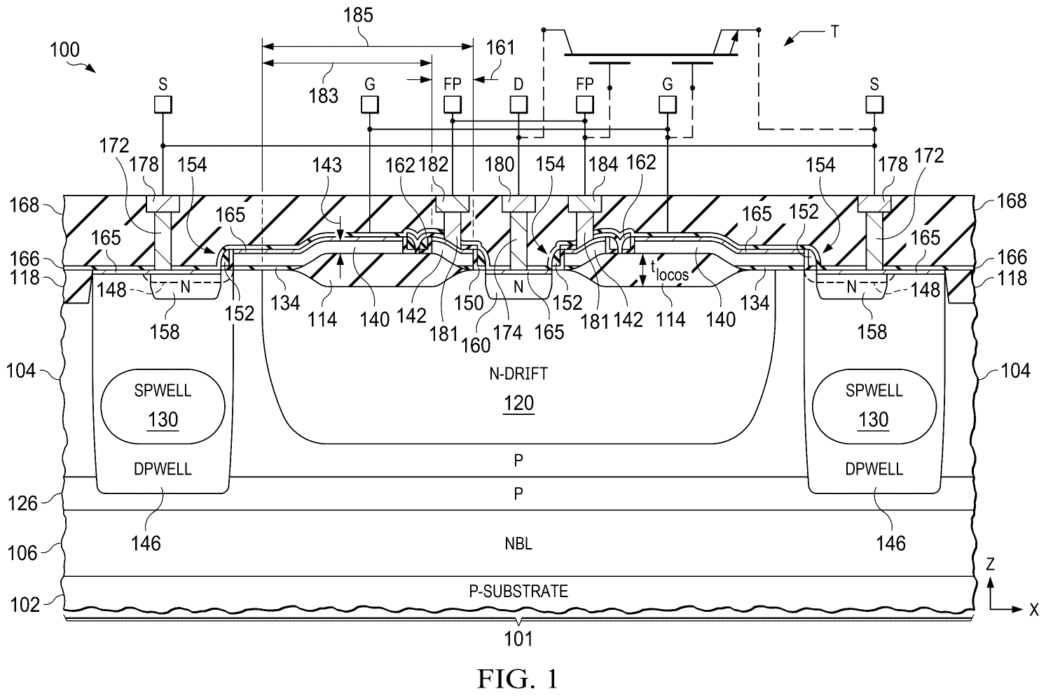

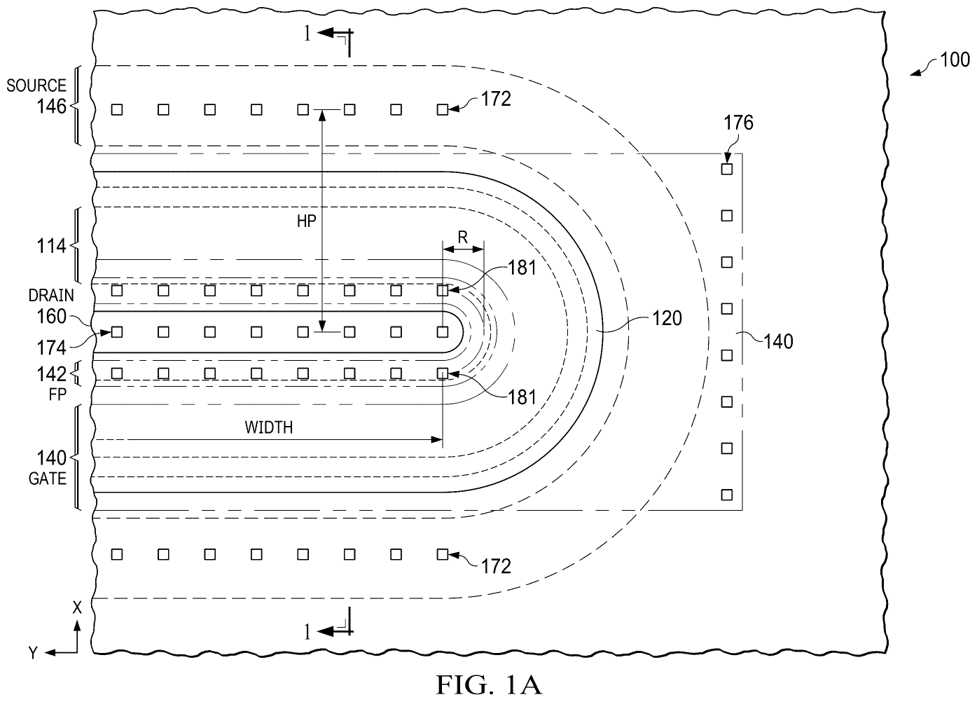

FIGS. 1 and 1A show a semiconductor device 100 that includes a drain extended transistor 101 with a biased field plate 142 having a lateral position and bias voltage determined by device model adjustment through simulation. The biased field plate 142 may also be referred to as a biased drain field plate. Described examples can enable improved off-state drift region electric field profile uniformity while maintaining good breakdown voltage performance with small half pitch dimensions without increasing the drift region length while maintaining low on-state resistance. Although scaling half pitch dimensions may be limited along the drift region by semiconductor breakdown strength and reducing the on-state resistance may be limited by the doping density and carrier mobility in the drift region, field plate positioning and biasing can be tailored for a given design specification through simulation and iterative model adjustment to provide benefits beyond the performance of a gate voltage biased field plate.

The semiconductor device 100 is shown in an example three-dimensional space with a first direction X (FIGS. 1 and 1A), a perpendicular (orthogonal) second direction Y (FIG. 1A), and a third direction Z (FIG. 1) that is perpendicular (orthogonal) to the respective first and second directions X and Y. Structures or features along any two of these directions are orthogonal to one another. The example drain extended transistor 101 is an n-channel laterally diffused metal oxide semiconductor (LDMOS) transistor. FIG. 1 shows a schematic representation of the drain extended transistor 101 labeled “T” with indicated connections to a gate G, a drain D and a source S as well as a field plate FP laterally disposed between the gate G and the drain D. In another implementation, p-channel LDMOS transistors can be formed when n-doped regions are substituted by p-doped regions and p-doped regions are substituted by n-doped regions in another implementation. In one example, further electronic components (not shown) may be provided in the semiconductor device 100, such as a second drain extended transistor interconnected with the illustrated transistor 101 in a half bridge circuit in a packaged integrated circuit with terminals or leads providing external connections to some or all of the transistor terminals. In some implementations, further circuitry can be included, such as gate driver circuits (not shown), switching control timing circuitry, etc., in a single integrated circuit for use in high voltage switching applications such as power conversion systems, transceivers, etc.

As further shown in FIG. 1, the example semiconductor device 100 includes a semiconductor substrate 102, such as including silicon or other semiconductor material from a starting wafer doped with impurities of a first conductivity type (e.g., P-type), such as a silicon (Si) or other semiconductor wafer (e.g., silicon carbide or SiC, gallium nitride or GaN, etc.), a silicon on insulator (SOI) wafer, etc. The semiconductor device 100 in one example includes a semiconductor layer 104 (e.g., p-type epitaxial silicon) that extends over the semiconductor substrate 102 and includes a body region 104 having the first conductivity type (e.g., P-type). An n-type buried layer (NBL) 106 extends under the semiconductor layer 104 and has an opposite second conductivity type (e.g., N-type). The device 100 includes a field relief dielectric layer 114, such as a local oxidation of silicon (LOCOS) layer of silicon dioxide (SiO₂). In one example, an isolation structure including shallow trench isolation 118 extends around the outer periphery of the transistor 101 along and into the top side of the semiconductor layer 104.

The semiconductor device 100 includes a drain drift region 120 (e.g., labelled “N-DRIFT” in FIG. 1) having the second conductivity type and extending in the body region 104. The field relief dielectric layer 114 extends over the drain drift region 120. As shown in FIG. 1A, the example drain extended transistor has a finger or racetrack shape with a center drain finger (e.g., labelled “D” in FIG. 1 and “DRAIN” in FIG. 1A), a polysilicon gate (e.g., labelled “G” in FIG. 1 and “GATE” in FIG. 1A) that encircles the drain, and a source (e.g., labelled “S” in FIG. 1 and “SOURCE” in FIG. 1A) that encircles the gate. In this or other examples, the transistor can include further drain-centered finger or racetrack structures (not shown). In these or other implementations, the transistor can include one or more source-centered finger or racetrack structures and/or one or more gate-centered finger or racetrack structures (not shown).

As further shown in FIG. 1, the example semiconductor device 100 can also include a p-type buried layer 126 (e.g., labelled “P”, also referred to as a pRESURF layer for safe operating area (SOA) improvement) with the first conductivity type and a dopant concentration greater than the body region 104. In one example, the body region 104 of the semiconductor layer includes a shallow well 130 (e.g., labeled “SPWELL” in FIG. 1) below the source S, with the first conductivity type (e.g., p-type) and a dopant density higher than that of the body region 104. The shallow well 130 increases a base doping level of the body region 104 to help suppress a parasitic lateral NPN bipolar transistor formed by an N+ source-p-body-N+ drain D, which may limit high current operation for the LDMOS transistor 101, thus restricting the safe operating area (SOA) of the LDMOS transistor 101.

The transistor 101 also includes a gate dielectric layer 134 with a racetrack shape (FIG. 1A) that extends over a portion of the body region 104 (FIG. 1). The gate dielectric layer 134 extends over a junction between the body region 104 and the drain drift region 120. The gate dielectric layer 134 in one example extends to outer bird's beak tapered portions of the field relief dielectric layer 114 and over the channel and an interface or junction between the p-type body region 104 and the n-type drift region 120 underneath a portion of the gate fingers or racetrack G. As further shown in FIGS. 1 and 1A, a polysilicon gate electrode 140 extends over the gate dielectric layer 134 and also over a portion of the field relief dielectric layer 114 above the drift region 120.

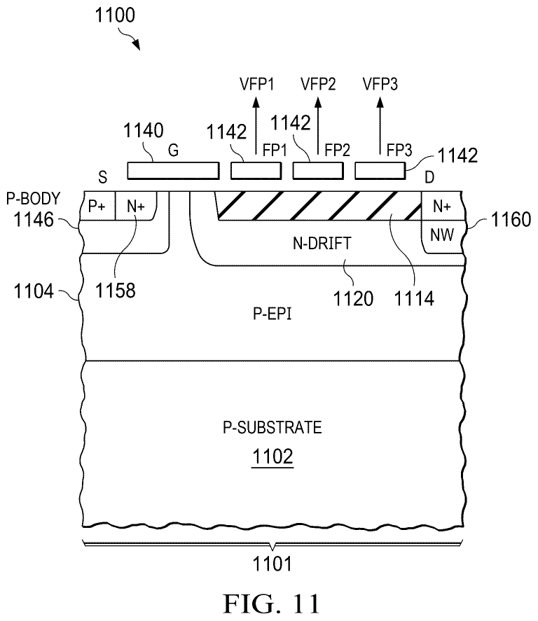

The transistor 101 has a biased field plate 142, which may also be referred to as a biased drain field plate, which is located over the field relief dielectric layer 114. The biased field plate 142 in this example also has a racetrack shape (e.g., labelled “FP” in FIGS. 1 and 1A). The biased field plate 142 is laterally spaced apart from the gate electrode 140 and is positioned laterally between the gate electrode 140 and the transistor drain. The field plate 142 is conductively connected to a biasing circuit (not shown) that provides a field plate bias voltage to the field plate 142 in powered operation of the semiconductor device 100. The illustrated example includes a single biased field plate 142. In other implementations (e.g., FIG. 11 below), two or more biased field plates can be provided that are spaced apart from one another and positioned laterally between the gate G and the drain D, with corresponding field plate dimensions and positions as well as field plate bias voltages determined according to an adjusted device model as described further below.

As shown in the example of FIG. 1A, the biased field plate 142 follows a path that has rounded corners with a radius R greater than a thickness 143 (e.g., along the third direction Z in FIG. 1) of the field plate 142. The field relief dielectric layer 114 in one example includes a local oxidation of silicon (LOCOS) layer of silicon dioxide, and the field plate 142 extends over a tapered edge of the field relief dielectric layer 114. In the illustrated example, the field plate 142 is located over a point (e.g., along the first direction X in FIG. 1) at which the LOCOS layer ends (e.g., where a bird's beak shape of the LOCOS field relief dielectric layer 114 begins) at a top surface of the semiconductor layer 104. In one example, the field plate 142 is or includes polycrystalline silicon and can be formed and patterned concurrently with the gate electrode 140.

The example drain extended transistor 101 also includes a source with a p-type deep well region 146 having the first conductivity type (e.g., labelled “DPWELL” in FIG. 1) that extends through and below the p-type shallow well 130. The p-type deep well region 146 extends to the top side of the body region 104 and connects to the p-type buried layer 126. An n-type well region 148 extends along the top side of the p-type deep well region 146 and has the second conductivity type. The example semiconductor device 100 also includes sidewall spacer structures 154 along the lateral sides of the gate electrode 140 and the field plate 142. The sidewall spacers 154 in one example include an oxide layer 150 and a nitride layer 152 formed by deposition and anisotropic etching. The sidewall spacers 154 overlap an edge of the field relief dielectric layer 114 adjacent to the drain region. In another example, a nitride layer 152 may be deposited across the surface of the wafer and etched to form a nitride-only sidewall spacer 154. The transistor 101 has a source region 158 with the second conductivity type (N-type) in the p-type deep well 146, where the source region 158 has a larger depth than the n-type well region 148.

The transistor drain includes a drain region 160 with the second conductivity type (N-type) extending along and into the top side of the drain drift region 120 in the body region 104 and the drain region 160 is laterally encircled by the field plate 142. The field plate 142 is spaced apart from, and extends laterally between, the gate electrode 140 and the drain region 160. The drain region 160 has a dopant density greater than the dopant density of the drain drift region 120. The field relief dielectric layer 114 extends from the gate dielectric layer 134 toward the drain region 160 and has a thickness greater than the gate dielectric layer 134. The field plate 142 in one example is electrically biased at a non-zero field plate bias voltage with respect to the substrate 102 or with respect to the source. In one example, the field plate 142 extends laterally between the drain region 160 and the gate by a field plate width dimension 161 (FIG. 1) that is at least twice the thickness along the third direction Z of the field relief dielectric layer 114 in one example. In the illustrated example, the field plate 142 extends on a thin bird's beak and of the field relief dielectric layer 114, although not a requirement of all possible implementations. As shown in FIG. 11 below, for example, one or more field plates can extend partially or entirely over portions of the field relief dielectric layer in other implementations.

The semiconductor device 100 in one example has a silicide blocking layer 162 (FIG. 1) that is or includes one or more sublayers of an oxide, a nitride, an oxynitride, or combinations thereof. The silicide blocking layer 162 in one example extends over the sidewall spacers 154 between the gate G and the biased field plate FP. In the illustrated example, the gate electrode 140 extends over the field relief dielectric layer 114 and the gate electrode 140 is laterally spaced apart from the field plate 142 by a portion of the silicide blocking layer 162 that extends on the sidewall spacer structures 154. The sidewall spacer on the sidewall of the field plate 142 extends to the drain region 160.

The semiconductor device 100 also includes a metal silicide layer 165 that extend along upper sides of the deep well region 146 of the source and of the drain region 160 to facilitate low resistance electrical connection to the source and drain terminals of the transistor 101. In addition, a metal silicide layer 165 can be provided for low resistance electrical connection to the biased field plate 142 and to the gate electrode 140 by conductive metal (e.g., tungsten) contacts including gate contacts in a gate contact region at the lateral ends of the finger structure (FIG. 1A). The semiconductor device 100 also includes a nitride etch stop layer 166 that extends over portions of the metal silicide 165, the sidewall spacers 154, and the silicide blocking layer 162.

The semiconductor device 100 can include a single or multilevel metallization structure, with a pre-metal dielectric 168 (PMD), conductive metal (e.g., tungsten) contacts 172 and 174 for the source and the drain (FIGS. 1 and 1A), gate contacts 176 (FIG. 1A), and field plate contacts 181 (FIGS. 1 and 1A). The illustrated portion of the metallization structure in FIG. 1 also shows metal interconnects 178 and 180 conductively coupled to the respective source and drain contacts 172 and 174, as well as metal interconnects 182 and 184 coupled to the field plate contacts 181, and similar metal interconnects (not shown) are coupled to the gate contacts 176 for electrical connection to the various terminals of the transistor 101 in the metallization structure. The metal interconnects 182 and 184 allow electrical connection of a bias voltage circuit (not shown) to bias the field plates 142 and a non-zero field plate bias voltage may be applied during operation of the semiconductor device 100.

The extended drain of the transistor 101 provides a relatively lightly doped drift region to extend the high voltage drain away from the edge of the channel region and the planar drift region can be used to increase the reverse blocking voltage beyond the voltage rating of the gate oxide 134 in a particular process. For even higher drain voltage rating, the drain side of the gate polysilicon is spaced from the drift region 120 by the field relief dielectric layer 114 to facilitate more complete depletion of the drift region. Reduced surface field (RESURF) profiled doping can be used for full reverse bias depletion of the drift region. The drift region doping level or dopant concentration in certain examples can be higher near the connection to the transistor channel region to mitigate channel hot carrier injection into the gate and enhance the transistor reliability. In addition, the biased field plate 142 facilitates enhanced uniformity of the electric field in the drift region 120 below the field relief oxide 114 in the off-state of the transistor 101 to facilitate good breakdown voltage performance of the transistor 101 without adversely impacting the on-state drain-source resistance and without having to increase the lateral length of the drift region along the first direction X.

In power switching circuits, such as DC-DC converters, a high-side switch and a low-side switch may be fabricated as drain extended transistors and a source/back gate terminal of the high-side device can be isolated from circuit ground to facilitate high-voltage operation. In addition, shrinking geometries and alignment tolerances of advanced semiconductor manufacturing processes increase the performance impact of non-uniformities such as center-edge differences in device structure locations. Scaling drain extended transistors to reduce the half pitch dimension along the first direction X and/or design of transistors with a fixed half pitch dimension to facilitate higher breakdown voltage ratings can inhibit the ability to balance off-state breakdown voltage performance with low on-state drain-source resistance.

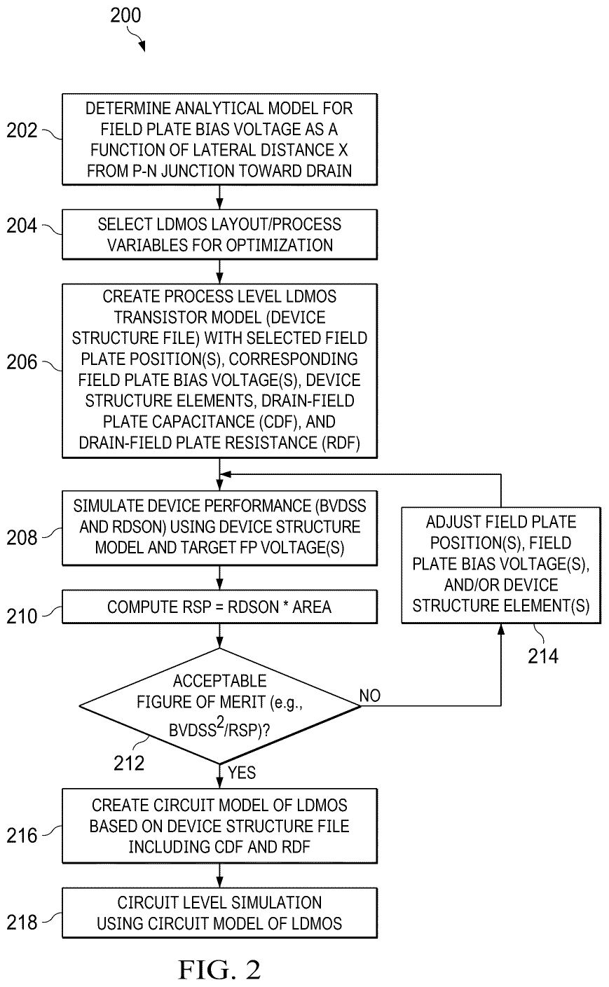

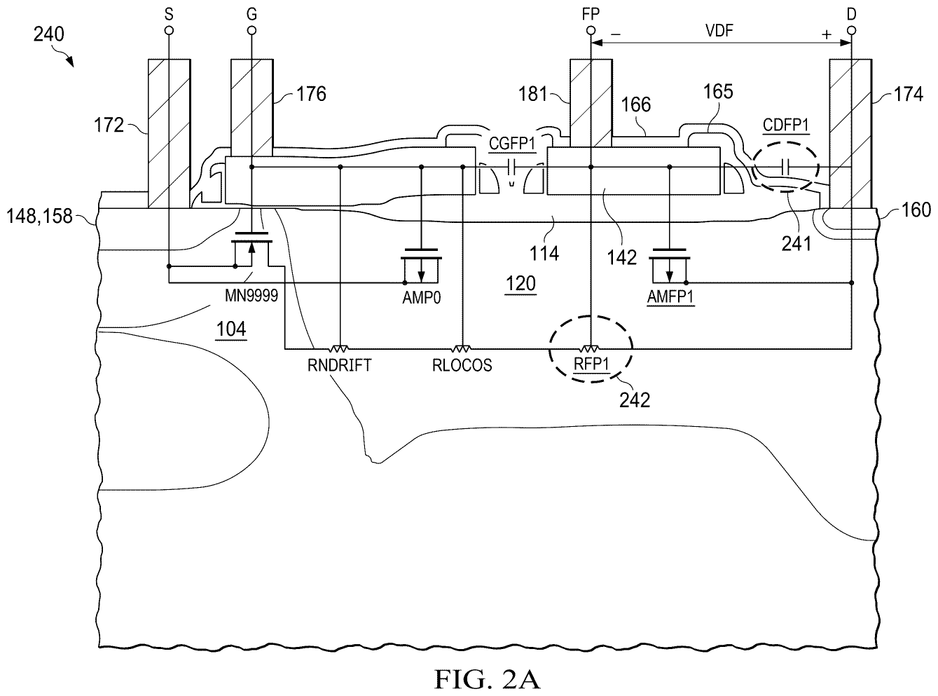

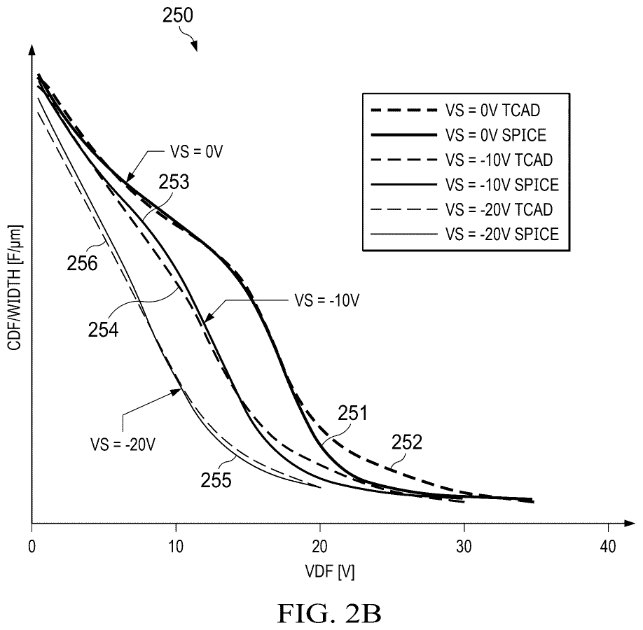

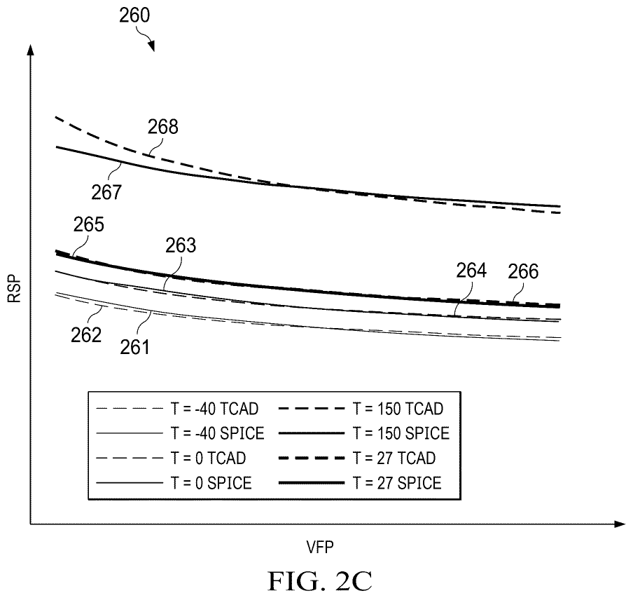

Referring also to FIGS. 2-2B, the improved electric field uniformity in the transistor off-state can be tailored for a given design of the field plate width dimension 161, the position of the lateral edges of the field plate 142 (e.g., the distances 183 and 185 in FIG. 1) from the body to drift region p-n junction and/or the bias voltage applied to the field plate 142 in operation, along with other structural and process values of the transistor 101 and the fabrication thereof. FIG. 2 shows a method 200 which can be used in the design and/or manufacturing (e.g., fabrication) of the semiconductor device 100 and the transistor 101 or other devices having one or more biased field plate drain extended transistors. FIG. 2A shows a partial side view TCAD cross-section with sub-circuit modeling components (resistors, capacitors, etc.) shown in a schematic representation of an extended drain transistor device model 240 of the above described drain extended transistor 101 with the biased field plate 142, a modeled drain-to-field plate capacitor 241 (e.g., labeled CDFP1 in FIG. 2A, also referred to as CDF) and a modeled drain-to-field plate resistor 242 (e.g., labeled RFP1 in FIG. 2A, also referred to as RDF). The modeled components in one implementation can be developed based on TCAD simulations to predict the device performance on the circuit level for use by circuit designers, for example, in developing a gate driver design or other circuit using a drain extended transistor. The model 240 also includes a mathematical model of the drain extended transistor (e.g., labeled MN9999 in FIG. 2A), a gate drift region modulator labeled AMP0, a field plate drift region modulator labeled AMFP1, a drift region resistance labeled Rndrift, and a field relief oxide (e.g., LOCOS) resistance labeled Rlocos. FIG. 2A illustrates the model 240 overlaid over the various numerically referenced structural elements of the example transistor 101 as described above in connection with FIGS. 1 and 1A. In this example, the contacts are illustrated as modeled (e.g., 172, 174, 176, 181) but do not need to all appear in the illustrated section, for example, where the gate contacts 176 in one example are at the end of the finger structure as shown in FIG. 1A and are not in the same section as the other contacts 172, 174 and 181.

The method 200 in one example can be used for designing a given implementation of the drain extended transistor 101, for example, to provide approximately linear distribution of electric field along the lateral length of the drift region along the first direction X by the sizing, positioning and biasing of the biased field plate 142. The method 200 can also be used in connection with other transistor designs having more than one biased field plate and more than one corresponding field plate bias voltages (e.g., FIG. 11 below). The method 200 provides an adjusted device model that can be used to fabricate a drain extended transistor (e.g., transistor 101 above) with a drain extended transistor drift region with enhanced off-state electric field profile uniformity, enabling optimally small drift length (e.g., which may be limited along the drift region by semiconductor breakdown strength) along with optimally low on-state resistance (e.g., which may be limited by the doping density and carrier mobility in the drift region). In the example transistor 101 of FIGS. 1 and 1A, the field relief dielectric layer 114 extends over the drain drift region 120 from the gate dielectric layer 134 toward the drain region 160 and has a thickness that is greater than the thickness of the gate dielectric layer 134. In this example, moreover, the biased field plate 142 is located over the field relief dielectric layer 114 and laterally positioned between the gate electrode 140 and the drain region 160.

In one example implementation of the method 200, the position, dimensions, and/or bias voltage of the field plate 142 is/are determined by adjusting the transistor device model 240 based on simulated performance of the drain extended transistor 101 using the device model 240. At 202 in FIG. 2, the method 200 includes determining an analytical model for the field plate bias voltage as a function of lateral distance (e.g., along the first direction X in FIG. 1) from the p-n junction of the source 148, 158 to the p-type body 104 toward the drain. In reference to FIG. 1 above, the example field plate 142 has a first lateral end spaced by the distance 183 from the body to drift region p-n junction along the first direction X, and the opposite second lateral end of the field plate 142 is spaced by the distance 185 from the body to drift region p-n junction, where the difference between the distances 183 and 185 is the width dimension 161 (e.g., lateral width) of the field plate 142.

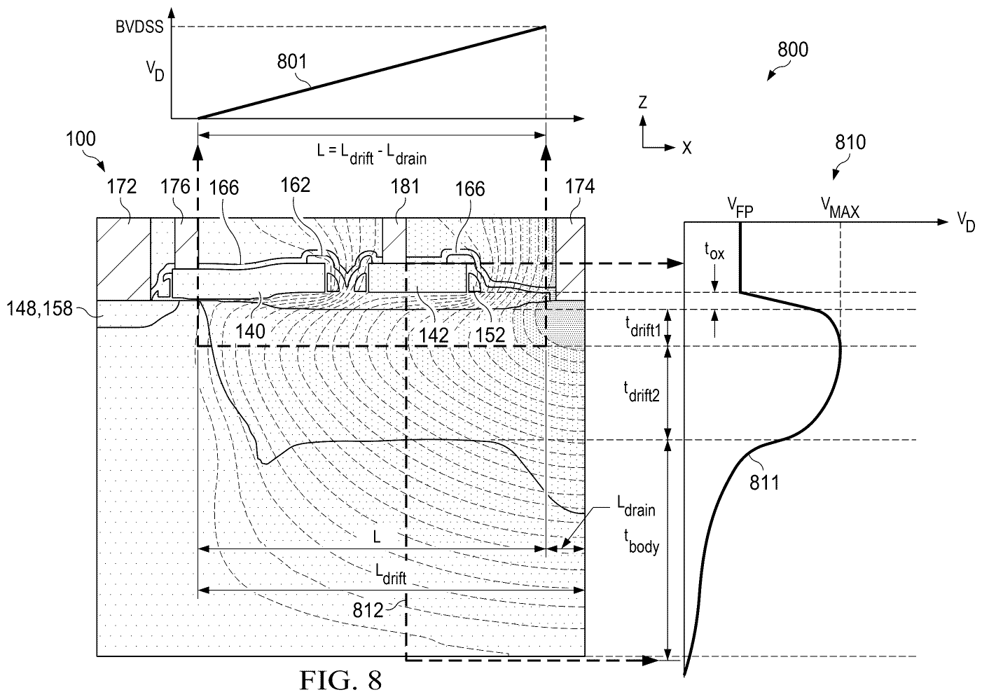

The analytical modeling at 202 and FIG. 2 in one example includes expression in the form of an analytical equation determining the field plate (FP) potential/position for a given LDMOS device. In one example, the analytical equation is a linear equation (1):

$$V F P ( x ) = f ( x ) = a x + b , \qquad ( 1 )$$

where “a” and “b” are dependent on the dopant concentration N_{D} of the drift region 120, the thickness t_{LOCOS} of the LOCOS field relief oxide 114 along the third direction Z (t_{LOCOS} in FIG. 1, tₒₓ in FIG. 8), the half pitch dimension of the transistor 101 (HP in FIG. 1A), and potentially other process and/or structure level parameters. In some examples, “a” and “b” can vary based on a voltage rating of a given device and/or based on a different manufacturing facility or process. The analytical equation of the device model 240 determines the initial inputs to start field plate position and/or biasing voltage optimization experiments using simulation and one or more iterations of device model adjustment based on the simulation. In one implementation, final biasing and position of the field plate 142 can be determined by sufficient trials of TCAD device simulation, as estimates and approximations made for the drift doping consideration and LOCOS thickness through analytical derivations at 202.

As shown in a graph 800 in FIG. 8, the linear equation in one example provides a linear breakdown voltage VB curve 801 (also referred to as BV or BVDSS) as a function of the distance along a length L including the length L_{drift} minus the length L_{drain} in the first direction X between the junction (e.g., the body to drift region p-n junction) and the drain of the modeled drain extended transistor 101. In the example of FIG. 8, the contacts are illustrated as modeled (e.g., 172, 174, 176, 181) but do not need to all appear in the illustrated section, for example, where the gate contacts 176 in one example are at the end of the finger structure as shown in FIG. 1A and are not in the same section as the other contacts 172, 174 and 181. FIG. 8 also includes a graph 810 with a curve 811 that shows the vertical voltage drop in the third direction Z simulated along a vertical section line 812 that extends through the field plate 142 as shown in FIG. 8, and which includes the thickness tₒₓ of that portion of the field relief oxide 114 (labeled “t_{LOCOS}” in FIG. 1), the thickness t_{drift1} of the top or first portion of the drift region 120 the thickness t_{drift2} of the bottom or second portion of the drift region 120, and the thickness t_{body} of the p-type body 104 below the drift region 120. The curve 811 in the graph 810 includes a maximum voltage Vₘₐₓ given by the following equation (2):

$${V}_{max} = {V}_{F P} ( x ) + Δ {V}_{t o p} = Δ {V}_{b o t t o m} , \qquad ( 2 )$$

where ΔVₜₒₚ is the voltage drop in the field relief oxide 114+ the voltage drop in the top side of the drift region 120, and ΔV_{bottom} is the voltage drop in the bottom side of the drift region 120+ the voltage drop in the body/epi region 104. In one example, the analytical derivation includes the following equations:

$${V}_{F P} ( x ) = {V}_{max} - Δ {V}_{t o p} = \frac{B V D S S}{L} x - Δ {V}_{t o p} for x \geq x\_GPR , \qquad ( 3 )$$

with a first assumption given by equation (4):

$$BVDSS = {BV}_{ideal} = \frac{{b}_{n} L}{ln ( {a}_{n} L )} , \qquad ( 4 )$$

where

$${a}_{n} = 7.03 \times 1 {0}^{5} \frac{1}{cm} and {b}_{n =} 1.47 \times 1 {0}^{6} \frac{V}{cm} ,$$

with a second assumption of constant N_{D} producing the following equation (5):

$$Δ {V}_{t o p} = \frac{q {N}_{D}}{{ε}_{s}} {t}_{drift 1} ( \frac{{ε}_{s}}{{ε}_{o x}} {t}_{o x} + \frac{{t}_{drift 1}}{2} ) \qquad ( 5 )$$

and a third boundary condition assumption for t_{drift1} calculation given by the following equation (6):

$$0 < {t}_{drift 1} < \frac{{t}_{d r i f t}}{2} , \qquad ( 6 )$$

where a narrower range is 0.1 μm≤t_{drift1}≤0.4 μm. This yields the following linear equation (7):

$${V}_{F P} ( x ) = \frac{B V D S S}{L} x - \frac{q {N}_{D}}{{ε}_{s}} {t}_{d r ift 1} ( \frac{{ε}_{s}}{{ε}_{o x}} {t}_{o x} + \frac{{c}_{d r ift 1}}{2} ) , \qquad ( 7 )$$

A breakdown field estimation at x=L yields the following:

At the surface in Si:

$${E}_{max}^{S i} = \frac{q {N}_{D}}{{ε}_{s}} {t}_{drift 1} \approx 0.55 \frac{MV}{cm} < {E}_{C}^{S i} \approx 0.6 \frac{MV}{cm} ,$$

At the surface in SiO₂:

$${E}_{max}^{SiO 2} = \frac{q {N}_{D}}{{ε}_{o x}} {t}_{drift 1} \approx 1.65 \frac{MV}{cm} < {E}_{C}^{SiO 2} \approx 10 \frac{MV}{cm} ,$$

and

In the bulk semiconductor material: E^{Si}=0 @ z=tₒₓ+t_{drift1},
where V_{D}=Vₘₐₓ, q is the free electron charge (also referred to as the elementary charge), N_{D} is the dopant concentration of the drift region, GPR is the right edge of the gate poly, tₒₓ is the field relief oxide thickness, t_{drift} is the drift region thickness, εₛ is the silicon permittivity, εₒₓ is the oxide permittivity (oxide=SiO₂), E^{Si}ₘₐₓ is the critical electric field of silicon, and E^{SiO2}ₘₐₓ is the critical electric field of silicon dioxide.

At 204 in FIG. 2, the example implementation of the method 200 includes selection of LDMOS transistor layout and/or process variables for optimization or improvement. The method 200 continues at 206 with creating the device model 240 of the drain extended transistor 101 with the biased field plate 142 based on the analytical modeling, followed by simulating the transistor performance at 208 using the device model 240. In one example, the transistor device model created at 206 is a process level model, such as a device structure file, with selected field plate position(s), corresponding field plate bias voltage(s), and may further include device structure elements, drain-field plate capacitance CDF, and drain-field plate resistance RDF parameters. In a first iteration, the transistor device performance is simulated at 208 in FIG. 2, for example, with respect to transistor off-state drain-source breakdown voltage BVDSS and on-state transistor drain-source resistance RDSON using the device model 240. In one example, the simulation is performed using predetermined (e.g., target) field plate position and bias voltage (or more than one bias voltage for the case of multiple biased field plates, such as in FIG. 11 below).

At 210 in FIG. 2, a specific resistance RSP is computed at 210 based on the simulated drain-source resistance RDSON (e.g., extracted from I_{D}-V_{G} plot with a small V_{DS}) and the simulated transistor area (e.g., a distance between a source and drain (e.g., HP in FIG. 1A) multiplied by the transistor width along the second direction Y (e.g., WIDTH in FIG. 1A)). The illustrated example implementation uses a figure of merit or acceptability criterion that is used to assess progressive transistor performance improvement through adjustment of the device model 240 in one or more iterations.

The illustrated implementation includes a determination at 212 as to whether the figure of merit is acceptable. The acceptability criterion used for the decision at 212 can be a figure of merit reaching or exceeding a given target (either increasing past a target, or decreasing past a different target), or exceeding a predetermined number of iterations, or a figure of merit being within a predetermined range that includes a desired target value.

If the figure of merit has not satisfied the acceptance criteria (NO at 212), a method 200 proceeds to 214, at which the device model 240 is adjusted based on the simulation to create an adjusted device model 240 to improve the figure of merit. Any suitable adjustment of one or more aspects of the device model 240 can be implemented at 214, for example, based on the specific type of figure of merit used in assessing acceptability at 212. In one example, the device model adjustment at 214 includes adjusting one or more of a field plate position, a field plate bias voltage VFP, and a device structure or element of the device model 240 based on the simulation to improve the figure of merit. In one example, the figure of merit is computed based on the off-state breakdown voltage BVDSS or the on-state resistance RDSON of the drain extended transistor 101. In this or another example, the figure of merit is computed based on both the off-state breakdown voltage BVDSS and the on-state resistance RDSON of the drain extended transistor 101. In this or a further example, the figure of merit correlates the off-state breakdown voltage BVDSS and the on-state resistance RDSON of the drain extended transistor 101.

In one implementation, the figure of merit is computed as a ratio of the square of a breakdown voltage BVDSS of the drain extended transistor 101 to the specific resistance RSP of the drain extended transistor 101 computed at 210 (e.g., BVDSS²/RSP). In one example, the adjustment at 214 of the device model 240 increases the figure of merit ratio (BVDSS²/RSP) of the drain extended transistor 101. Subsequent simulation is performed at 208 using the adjusted device model 240. Updated specific resistance information is computed at 210 and the figure of merit is revaluated at 212. In one implementation, the evaluation at 212 determines whether the most recent adjustment at 214 yielded an improvement in the computed figure of merit (e.g., an increase in BVDSS²/RSP). In one example, the evaluation at 212 can include a determination of one or more acceptance conditions, such as comparison of the most recent computed figure of merit with a target value or target range and/or a determination that a maximum number of iterations has occurred, and/or a determination that a local maxima (or local minimum) in the figure of merit has been reached in the most recent or in a previous iteration, indicating that further improvement is unlikely. In the above example, increasing the figure of merit ratio BVDSS²/RSP balances the off-state breakdown voltage of the modeled transistor 101 with the desirability of low on-state drain-source resistance for a given half pitch dimension of the evaluated device design.

Once the acceptance criterion has been met (YES at 212), the method 200 proceeds to 216 in FIG. 2, where a circuit model of the transistor is created based on the updated/adjusted device structure file (the updated device model 240). At 218 in FIG. 2, the method 200 in one example proceeds with circuit level simulation (e.g., SPICE model simulation or modeling of nonlinear circuits with small signal analysis, such as including quiescent point calculation at which the circuit is linearized) using the circuit model of the transistor 101 created at 216. The simulation at 218 can include small signal analysis, sensitivity analysis, poll-zero analysis, small-signal distortion analysis and other features. The method 200 in one example can include selective readjustment of the device model based on the circuit level simulation at 218, although not a requirement of all possible implementations. In one example, the method 200 can include fabricating an integrated circuit (e.g., semiconductor device 100 above) with a drain extended field plate biased transistor 101 based on the circuit model and/or the device model 240.

The method 200 can be implemented in a variety of different manners, such as modeling breakdown and on-state conduction performance to determine beneficial field plate size and position values given a starting drift length or half pitch dimension, a given field relief oxide thickness and field plate bias voltage(s). In another example, a method 200 can be performed given starting drift length or half pitch dimension, a given field relief oxide thickness and field plate dimensions and position values to determine beneficial field plate bias voltage(s). A variety of different approaches can be used, and the illustrated examples provide optimization or at least enhancement of LDMOS characteristics (e.g., BVDSS, RDSON, etc.) based on a desired transistor operating voltage rating, and creation of device and circuit models of the transistor with an approximately linear relationship between drain field plate position(s) and field plate bias voltage(s). Device simulation based on the linear relationship and one or more iterations of simulation and model adjustment can beneficially improve one or more figures of merit for circuit model development of the LDMOS based on multiple distinctive electrical behaviors of the LDMOS transistor 101.

Referring also to FIGS. 2B and 2C, in certain examples, the device model 240 and the circuit model created at 216 can include a drain-to-field plate capacitance CDF of the drain extended transistor 101 (e.g., labeled CDFP1 in FIG. 2A) and/or a drain-to-field plate resistor RDF (e.g., labeled RFP1 in FIG. 2A). FIG. 2B shows a graph 250 with example curves 251-256 showing non-linear drain-to-field plate capacitance (CDF) modeling results as a function of V_{DF} (the bias applied between the field plate and the drain as shown in FIG. 2A). Moreover, the capacitance CDF is simulated with three different voltages applied to the source (e.g., V_{S}=0V, −10V, −20V, respectively) while the voltage applied to the drain (V_{D}) increases and the voltage applied to the field plate is set at 0V. As shown in FIG. 2B, the capacitance CDF is modulated based on voltages applied to the drain and the source in one implementation of the extended drain transistor device model 240 of FIG. 2A and a SPICE circuit model created at 216.

The drain-to-field plate capacitance CDF in one example is non-linear, and beyond a certain voltage (e.g., approximately 15 V with respect to the curves 251 and 252 in FIG. 2B), the capacitance CDF drops relatively quickly because of depletion of electrons from the n-drift region (e.g., drain drift region 120). In one implementation of the device model 240 and the circuit model created at 216 in FIG. 2, the depletion voltage (e.g., at which the capacitance CDF drops quickly) is calculated using a first parameter VPO (pinch-off voltage), and an if-statement is used to calculate the charge (e.g., allowing the capacitance estimation) before and after the depletion voltage. In this implementation of the circuit model (e.g., and the device model 240), a second parameter DU is introduced to smooth out the capacitance transition between those two regions. In other words, the drain-to-field plate capacitance CDF of the circuit model can vary in a non-linear fashion with respect to a drain voltage V_{D} of the drain extended transistor 101, where the circuit model includes the second parameter DU to smooth a transition of the drain-to-field plate capacitance CDF caused by the drift region depletion as a function of a drain voltage V_{D} of the drain extended transistor 101. The following set of equations illustrates example SPICE modeling equations including the parameters VPO and DU (and wdep representing the depletion dimension that causes the non-linear capacitance behavior) for simulating the non-linear behavior of the capacitance CDF:

```
  vfb = vt − phis − K1*sqrt(phis) + KVTHO*vgds;
  vpoeff = VPO+KVPO*vgds;
  vce = vpoeff*(sqrt(1+4*DU*DU)−2*DU);
  vred = sqrt((vbdseff−vce)*(vbdseff−vce)/(4*vpoeff*vpoeff)+(DU*vce)/vpoeff) +
qrt((vbdseff+vce)*(vbdseff+vce)/(4*vpoeff*vpoeff)+(DU*vce)/vpoeff);
  tmp = vgds − vfbeff − vbdseff/vred − vgdsteff;
  if (tmp>=0) begin
    wdep = cox*(K1*(sqrt(0.25*K1*K1+tmp)−0.5*K1)+K2*tmp)/(‘P_Q*NCH);
    qdep = weff*leff*MULT*‘P_Q*NCH*wdep;
  end else begin
    qdep = weff*leff*MULT*cox*tmp;
  end
```

In this or another example, moreover, the drain-to-field plate capacitance CDF of the circuit model varies in a non-linear fashion with a voltage applied to the source (e.g., a source voltage V_{S}) of the drain extended transistor 101 as shown in FIG. 2B. The circuit model can include a third parameter KVPO to simulate modulation of the drain-to-field plate capacitance CDF caused by the voltage applied to the source (V_{S}), which in turn, modulates the depletion voltage. Moreover, the circuit model can include a fourth parameter KVTHO to simulate the capacitance CDF modulation due to the voltage applied to the field plate (V_{FP})—e.g., V_{FP} at zero, which may change a threshold voltage of the drift region under the field plate. The modeled non-linear behavior of the capacitance CDF with respect to the source voltage may account for electrons being pushed away from the n-drift region by the source bias.

In this example, the depletion voltage can be calculated using the first parameter VPO for the device model 240 and the circuit model created at 216. An if statement is used to calculate the capacitance (e.g., estimating the charge and the depletion dimension) before and after depletion, and the second parameter DU facilitates simulating the capacitance transition between the regions (e.g., smoothing out the transition). Moreover, the fourth parameter KVTHO is included in the device and circuit models so as to account for the capacitance modulation due to the voltage applied to the field plate, where the third parameter KVPO models the modulation of the depletion voltage (e.g., as a function of the voltage applied to the source).

The curve 251 in the graph 250 of FIG. 2B shows non-linear characteristics of the capacitance CDF as a function of V_{DF} (the bias applied between the field plate and the drain as shown in FIG. 2A) based on the SPICE circuit model at zero source voltage (V_{S}=0V), and the curve 252 shows a corresponding curve of TCAD results based on the transistor 101 under the same bias condition. In one implementation, the circuit model (e.g., and the device model 240) include parameters described above to simulate the modulation of the drain-field plate capacitance CDF (e.g., caused by V_{D}, V_{S}, V_{FP}) based on the TCAD results of the curve 252. The graph 250 also includes curves 253 and 254 respectively showing the SPICE modeling and TCAD results for the same design with a source voltage of −10 V (V_{S}=−10V). The graph 250 further includes curves 255 and 256 respectively, showing the SPICE modeling and TCAD results for the same design with a source voltage of −20 V (V_{S}=−20V).

In this or another example, the device model 240 and the circuit model created at 216 include the drain-to-field plate resistor RDF. FIG. 2C shows a graph 260 with example curves 261-268 showing modeling results of the drain-to-source specific resistance RSP including the effects of the drain-to-field plate resistor RDF as a function of the field plate bias voltage (V_{FP}) in one implementation of the extended drain transistor model of FIG. 2A. The resistance between the drain and the source is modulated by the biased field plate 142, because a positive bias at the field plate attracts additional electrons to the n-drift region (e.g., drain drift region 120), resulting in reduced resistivity of the n-drift region. In this example of the device and circuit models, the drain-to-field plate resistor RDF is used below the field plate 142 to model the drain region resistance. The drain-to-field plate resistor RDF of the circuit and device models estimates the n-drift region resistance based on the potential applied to the field plate 142, where the drain-to-field plate resistor RDF of the circuit model may vary in a non-linear fashion with respect to a field plate bias voltage V_{FP} applied to the field plate 142. In the graph 260, the curves 261, 263, 265, and 267 represent SPICE modeling results based on the circuit model, and the curves 262, 264, 266, and 268 show corresponding TCAD results, and agreement between the SPICE modeling results and TCAD data confirm the SPICE modeling accuracy. In certain implementations, the circuit model accounts for the differences in the pairs of curves shown in the graph 260 with respect to the modeled drain-to-field plate resistor RDF, and the sets of curve pairs represent the specific resistance RSP of the device at different corresponding temperatures T (degrees C.) as indicated in the legend of FIG. 2C. Higher temperature results in higher specific resistance RSP because of the positive temperature coefficient effect of the RSP, and higher field plate potential reduces the RSP due to more carrier accumulation in the drift region (e.g., drain drift region 120).

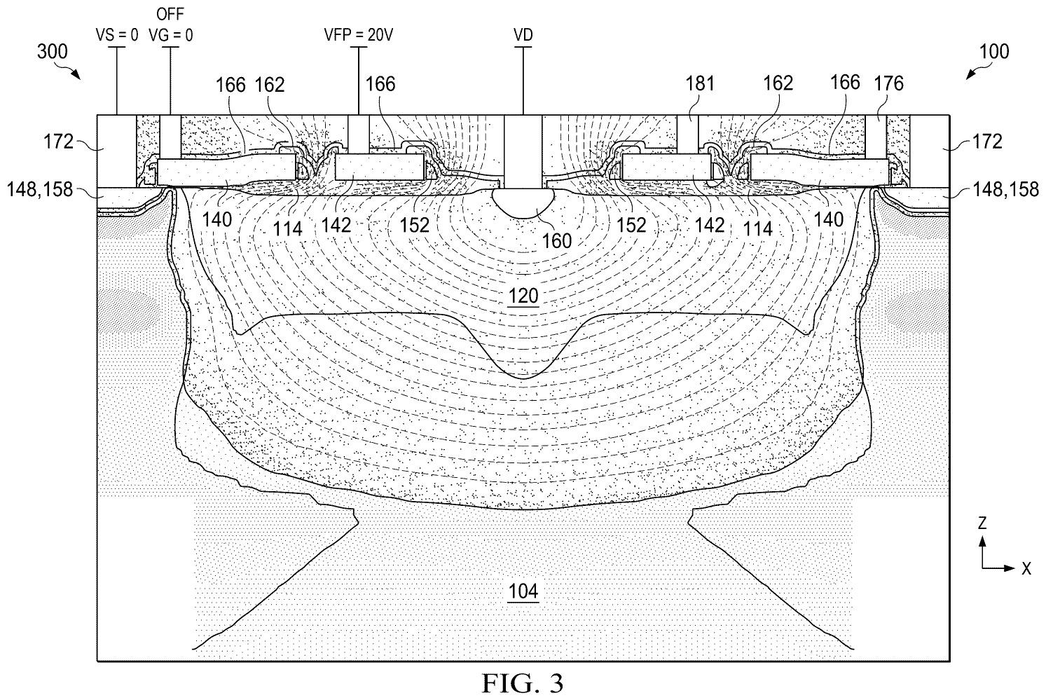

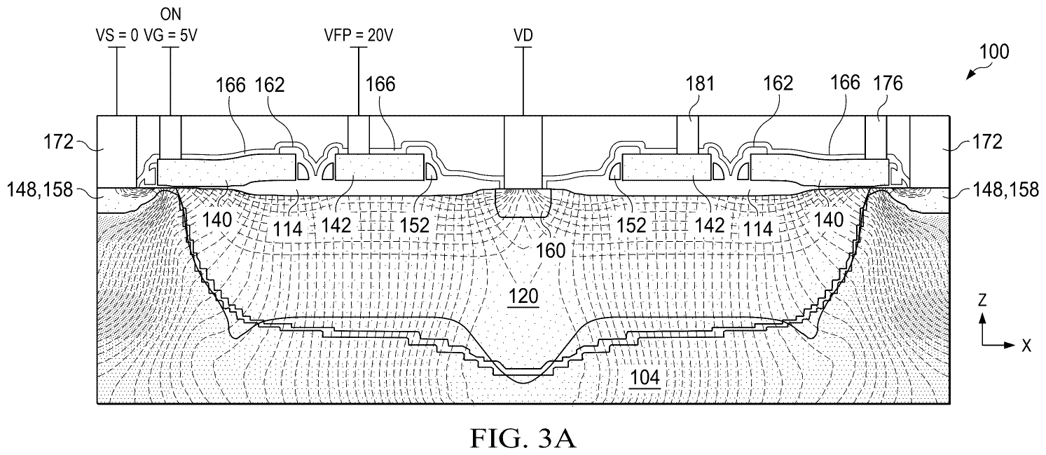

The method 200 and the electronic device 100 described above accommodate device and/or circuit area scaling with small half pitch dimensions while concurrently balancing the off-state breakdown voltage performance and low on-state resistance of the transistor 101. FIG. 3 shows a graph 300 with simulated off-state breakdown voltage operation of a 40 V transistor with a field plate biased to approximately 20 V including simulated net carrier distribution (shown as different shadings) outside the drain drift region 120, equipotential lines, and electric field magnitude shading within the drain drift region 120 as well as around the drain drift region 120. This simulation of the transistor off-state shows more uniform drift region charge balance with more uniform electric field distribution (as well as more uniform equipotential line distribution) along the length of the drift region in the first direction X compared to using no field plate or using a field plate biased to the gate voltage. As shown in this simulation, some of the equipotential lines escape between the gate electrode 140 and the biased field plate 142, relieving drain stress. This results in a more ideal drift region charge balance and facilitates a smaller half pitch dimension to achieve a given breakdown voltage rating for the transistor 101 and the device 100.

FIG. 3A is a graph of on-state operation of the 40 V transistor of FIG. 3 with the field plate biased to 20 V including simulated net carrier distribution (shown as different shadings), electron quasi Fermi levels, and current flow between the drain and the source (e.g., lines generally perpendicular to the electron quasi Fermi levels) showing the biased field plate accumulating charge carriers in the transistor channel and reducing the on-state drain-source resistance below what could be achieved without the biased field plate with the same transistor half pitch dimension. In the on-state, the field plate bias at 20 volts for a 40 volt rated transistor 101 accumulates the channel (e.g., accumulating electrons in the drain drift region) and reduces the RDSON below what could be achieved with a LDMOS design without the field plate biasing scheme. In certain implementations, the field plate can have any voltage in the on-state, and higher positive voltage is more favorable resulting in more drift region accumulation in the on-state as long as the field relief dielectric layer 114 (e.g., LOCOS, STI, gate oxide, etc.) supports the positive voltage without breaking down.

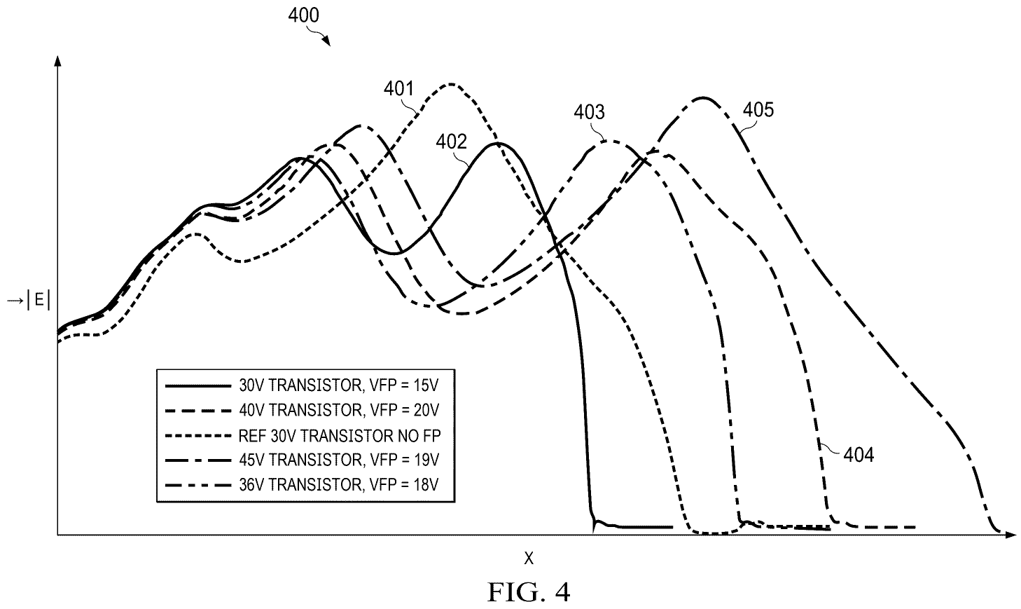

FIGS. 4-7 show further examples to demonstrate the enhanced drift region electric field uniformity performance and low on-state resistance in the drain extended transistor design with different design voltage ratings. In these examples, the single biased field plate 142 uses a bias voltage of approximately half the transistor rated voltage, with the goal of enhancing breakdown voltage uniformity across the length of the drift region during off-state voltage blocking operation of the transistor 101. The use of half the rated voltage as the single field plate bias voltage is one example, and other implementations are possible that deviate from this value. In particular, the iterative modeling and adjustment based on simulation of the device model can be used to achieve the balance between off-state breakdown voltage performance and on-state conduction based on any starting field plate size/position and field plate bias voltage levels.

FIG. 4 shows a graph 400 of electric field strength as a function of lateral position along a transistor drift region for a reference transistor with no field plate and transistors with different voltage ratings and a field plate biased at approximately half the rated voltage. In the transistor off-state, for example, a low side transistor in a half bridge circuit configuration with high drain voltage, the biased field plate 142 forces about half the voltage to drop between gate and the field plate 142, and the rest of the voltage is dropped between the field plate 142 and the drain, which beneficially makes the electric field in the drift region more uniform even for small half pitch dimensions.

A curve 401 in FIG. 4 shows the absolute value of the electric field strength as a function of lateral distance in the second direction X between the junction and the drain for a reference drain extended transistor with no field plate and a voltage rating of 30 V. A curve 402 in FIG. 4 shows a 30 V rated transistor with a biased field plate 142 biased to a voltage of approximately 15 V. Comparing the curves 401 and 402, the curve 402 demonstrates significantly improved electric field uniformity along the drift distance and significantly lower peak electric field, resulting in enhanced voltage breakdown performance of the transistor 101. The graph 400 includes further examples, with a curve 403 showing a 36 V rated transistor with a biased field plate 142 at a field plate bias voltage of approximately 18 V, with electric field uniformity advantages compared to the reference transistor of the curve 401. A curve 404 in FIG. 4 shows a 40 V rated transistor with a field plate 142 biased to approximately 20 V, and a further example curve 405 shows a transistor example rated at 45 V with a single field plate biased to approximately 19 V. The curve 405 in this example shows a slightly elevated second peak closer to the drain which is significantly higher than the earlier peak nearer to the source, but still provides improved voltage breakdown electric field uniformity compared to using no field plate or a field plate biased to the gate voltage.

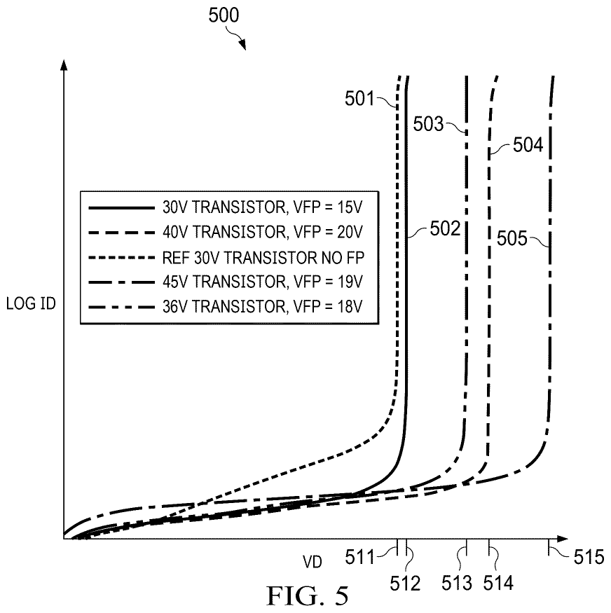

FIG. 5 shows a graph 500 of a breakdown voltage sweep of off-state transistor drain current (Log ID) as a function of drain-source voltage VD for the reference transistor with no field plate and the transistor (e.g., transistor 101) with different voltage ratings and a field plate biased at approximately half the rated voltage, using the same example transistor half pitch dimension and voltage ratings as the examples of FIG. 4. A curve 501 in this example illustrates the off-state drain current performance for the reference drain extended transistor with no field plate and a voltage rating of 30 V. A curve 502 in FIG. 5 shows the 30 V rated transistor with a biased field plate 142 biased to a voltage of approximately 15 V. Comparing the curves 501 and 502, the curve 502 demonstrates improved voltage breakdown performance of the transistor 101 with a breakdown voltage 512 that is greater than the breakdown voltage 511 of the reference transistor curve 501. The graph 500 includes a curve 503 showing the 36 V rated transistor with a field plate 142 at a field plate bias voltage of approximately 18 V, with a resulting breakdown voltage 513. A curve 504 in FIG. 5 shows the 40 V rated transistor with a field plate 142 biased to approximately 20 V and a corresponding breakdown voltage 514, and a curve 505 shows the 45 V transistor example with a single field plate biased to approximately 19 V and a breakdown voltage 515. As demonstrated in FIG. 5, the biased field plate provides good breakdown voltage performance with high BVDSS in these examples of FIG. 5 corresponding to the beneficial field shaping and uniformity shown in the curves 402-405 of FIG. 4 above.

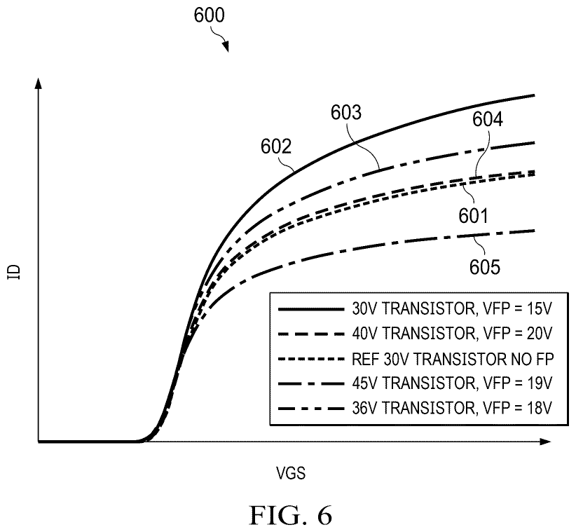

FIG. 6 shows a linear drain current sweep graph 600 with curves 601-605 illustrating on-state transistor drain current ID as a function of the gate-source voltage VGS for the reference 30 V transistor with no field plate (curve 601) and the above described example transistors with different voltage ratings and a field plate biased at approximately half the rated voltage (curve 602-605). The curves 601 and 602 corresponding to the 30 V rated transistor with no field plate and with a 15 V biased field plate, respectively, illustrate improved drain current performance with the biased field plate 142, and the other curves 603-605 illustrate similar good performance for transistor designs of a different voltage rating, where the simulated 45 fold transistor with 19 V field plate biasing shows comparatively lower drain current performance than the other examples where the field plate 142 is biased to approximately half the rated voltage. With respect to advantages of low RDSON and high linear drain current, the curves 602-604 show benefits facilitated by drift region accumulation as a result of the approximately mid voltage field plate bias level.

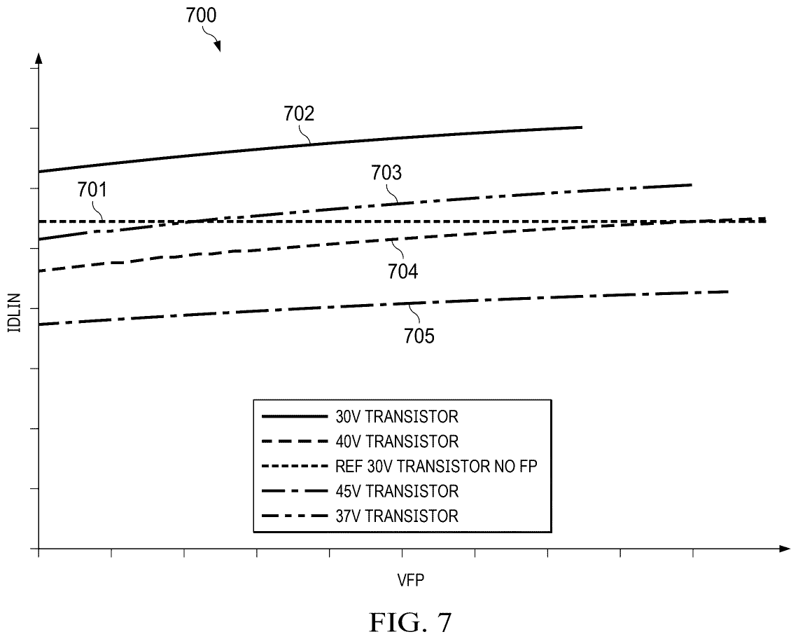

A graph 700 in FIG. 7 shows linear drain current (IDLIN) with relatively high gate-source voltage in the transistor on-state as a function of field plate bias voltage VFP for the above-described reference transistor with no field plate and the transistors with different voltage ratings and a biased field plate. In this example, the 30 V reference transistor with no field plate demonstrates a reference linear drain current in curve 701, and the curve 702 shows a relatively higher linear drain current for the 30 V transistor with the biased field plate 142, indicating beneficial improvement with respect to on-state performance as a result of the field plate biasing. The curves 702-704 illustrate similar beneficial performance, with the curve 705 showing a somewhat lower linear drain current for the 45 V transistor with a biased field plate 142.

As discussed above, FIG. 8 shows the example extended drain transistor of the semiconductor device 100 with the graph 800 showing the ideal linear curve 801 of off-state drift region voltage as a function of lateral distance along the first direction X from the source to the drain and the graph 810 shows the simulated voltage curve 811 as a function of vertical depth along the third direction Z, with simulated equal potential lines illustrated in the off-state.

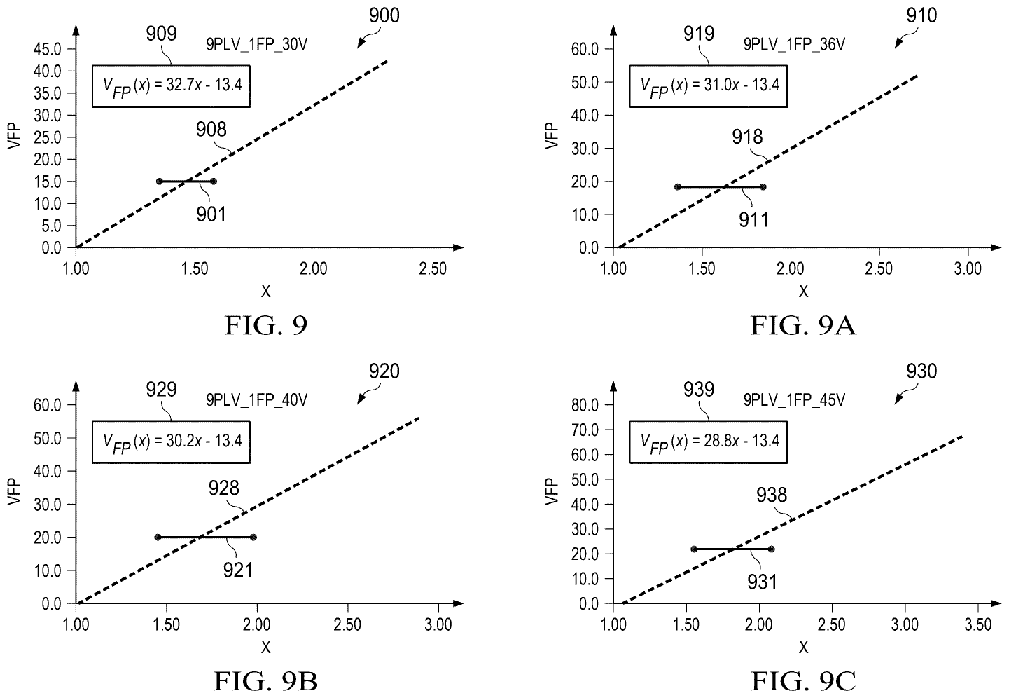

FIGS. 9, 9A, 9B, and 9C show respective graphs 900, 910, 920, and 930 with respective ideal linear field plate bias voltage curves 908, 918, 928, and 938 (VFP) as a function of lateral distance from the source to the drain along the first direction X. The graphs 900, 910, 920, and 930 also show respective simulated lateral positions shown as horizontal bars 901, 911, 921, and 931 (e.g., corresponding to the field plate width dimension 161 and the distances 183 and 185 in FIG. 1 above) of corresponding single biased field plates 142 for the transistors with different voltage ratings of 30 V, 36 V, 40 V, and 45 V, respectively. The individual graphs 900, 910, 920, and 930 further show corresponding linear field plate bias voltage equations 909, 919, 929, and 939 (e.g., implementations of equation (1) above) as a function of the lateral distance or position along the first direction X. The iterative adjustment of the device model 240 to create the circuit model (e.g., at 216 in FIG. 2 above) help to ensure that the biased field plate examples represented by the bars 901, 911, 921, and 931 are positioned along the respective ideal linear analytical model curves 908, 918, 928, and 938, and provide the off-state electric field uniformity benefits demonstrated in FIGS. 4-7 above without adversely impacting on-state low resistance and without increasing the transistor half pitch dimension.

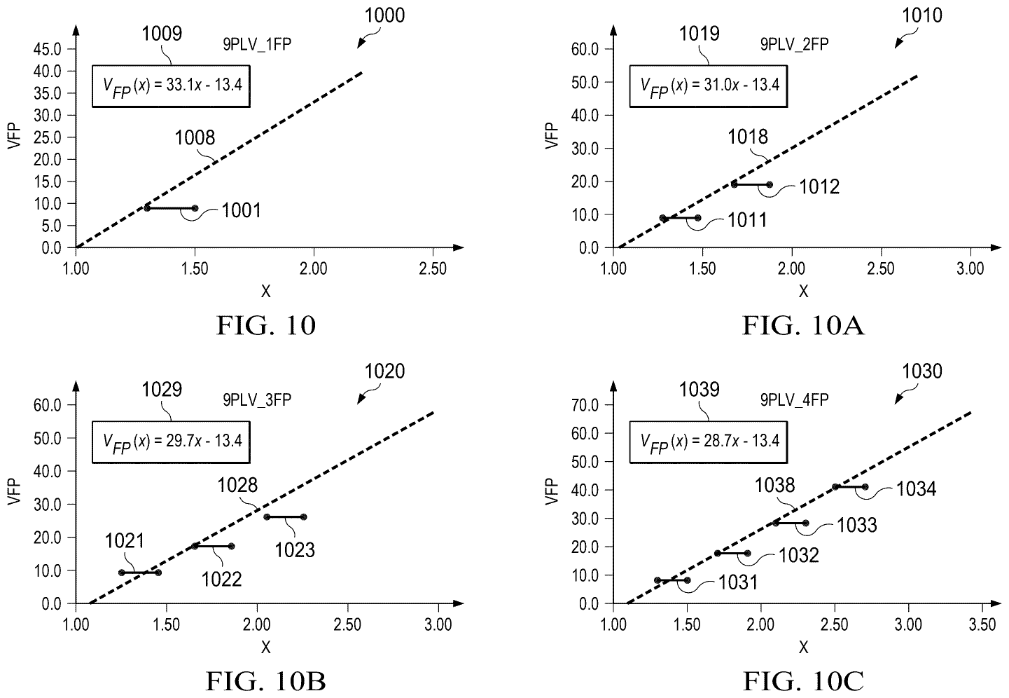

FIGS. 10, 10A, 10B, and 10C show respective graphs 1000, 1010, 1020, and 1030 of field plate bias voltage V_{FP} as a function of lateral distance from the source to the drain along the first direction X with an ideal linear modeled curve and simulated single and multiple biased field plates. The graphs 1000, 1010, 1020, and 1030 represent iterative modeling and simulation-based model adjustment for a respective single biased field plate example (graph 1000), an example having two biased field plates (graph 1010), another example having three biased field plates (graph 1020), and an example with four biased field plates 142 (graph 1030). The respective graphs 1000, 1010, 1020, and 1030 include ideal linear field plate bias voltage curves 1008, 1018, 1028, and 1038 as well as corresponding linear field plate bias voltage equations 1009, 1019, 1029, and 1039 (e.g., implementations of equation (1) above). The graph 1000 includes a single horizontal bar 1001 that corresponds to the field plate width dimension 161 and the distances 183 and 185 in FIG. 1 above for the single biased field plate implementation. The graph 1010 shows first and second horizontal bars 1011 and 1012 corresponding to respective first and second biased field plates which are biased at the respective vertical axis voltage levels shown in the graph 1010. The graph 1020 illustrates three horizontal bars 1021, 1022, and 1023 that correspond to three respective biased field plates (e.g., similar to field plates FP1, FP2, and FP3 in FIG. 11 below), and the final graph 1030 in FIG. 10 shows four horizontal bars 1031, 1032, 1033, and 1034 with different respective vertical axis bias voltages and horizontal axis start and end locations along the second direction X.

FIG. 11 shows another example semiconductor device 1100 that includes a drain extended transistor 1101 with three biased field plates 1142 (e.g., labeled FP1, FP2, and FP3) spaced apart from one another between a gate electrode 1140 and the transistor drain D. The device 1100 in FIG. 11 includes a p-substrate 1102, a body region with p-type epitaxial silicon 1104, a p-type implanted body region 1146, an n-type drift region 1120, as well as a drain 1160 and a source S with an implanted region 1158, which can be similar in some respects to the respective structures 142, 140, 102, 104, 146, 120, 160, and 158 as illustrated and described above in connection with FIGS. 1 and 1A. In other implementations, any integer number of biased field plates can be used, with corresponding field plate bias voltages to enhance the uniformity of electric field effects during off-state operation of a drain extended transistor, without significantly adversely impacting the desired low on-state resistance (RDSON) and without requiring increase in the half pitch or other dimensions of the drain extended transistor to facilitate high power density and small form factor electronic devices.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present description should not be limited by any of the above described examples. Rather, the scope of the disclosure should be defined in accordance with the following claims and their equivalents. Modifications are possible in the described examples, and other implementations are possible, within the scope of the claims.

What is claimed is:

1. A method, comprising:
creating a device model of a drain extended transistor with a biased field plate;
simulating performance of the drain extended transistor using the device model;
adjusting the device model based on the simulation to create an adjusted device model to improve a figure of merit; and
creating a circuit model of the drain extended transistor based on the adjusted device model.

2. The method of claim 1, wherein adjusting the device model based on simulating the performance includes adjusting one of a field plate position, a field plate width dimension, a field plate bias voltage, and a device structure or an element of the device model.

3. The method of claim 2, wherein the figure of merit is computed based on one of an off-state breakdown voltage and an on-state resistance of the drain extended transistor.

4. The method of claim 3, wherein the figure of merit correlates the off-state breakdown voltage and the on-state resistance of the drain extended transistor.

5. The method of claim 4, wherein adjusting the device model increases a ratio of a square of a breakdown voltage of the drain extended transistor to a specific resistance of the drain extended transistor.

6. The method of claim 1, wherein the circuit model includes a drain-to-field plate capacitance of the drain extended transistor as a function of a voltage applied to a drain of the drain extended transistor.

7. The method of claim 6, wherein the circuit model includes a parameter to smooth a transition of the drain-to-field plate capacitance, the transition caused by depleting a drift region of the drain extended transistor.

8. The method of claim 6, wherein the circuit model includes a parameter to simulate modulation of the drain-to-field plate capacitance caused by a voltage applied to a source of the drain extended transistor.

9. The method of claim 6, wherein the circuit model includes a drain-to-field plate resistance of the drain extended transistor.

10. The method of claim 6, wherein the drain-to-field plate capacitance of the circuit model varies in a non-linear fashion with a voltage applied to a drain of the drain extended transistor.

11. The method of claim 10, wherein the drain-to-field plate capacitance of the circuit model varies in a non-linear fashion with a voltage applied to a source of the drain extended transistor.

12. The method of claim 10, wherein the circuit model includes a drain-to-field plate resistance of the drain extended transistor.

13. The method of claim 6, wherein the drain-to-field plate capacitance of the circuit model varies in a non-linear fashion with a voltage applied to a source of the drain extended transistor.

14. The method of claim 1, wherein the circuit model includes a drain-to-field plate resistance of the drain extended transistor.

15. The method of claim 14, wherein the drain-to-field plate resistance of the circuit model varies in a non-linear fashion with a voltage of the biased field plate.

16. A semiconductor device, comprising:
a drain extended transistor having a semiconductor layer over a semiconductor substrate, the semiconductor layer including a body region having a first conductivity type and a drain drift region having a second, opposite, conductivity type;
a gate dielectric layer over the body region and extending over a junction between the body region and the drain drift region;
a gate electrode over the gate dielectric layer;
a drain region having the second conductivity type in the drain drift region, the drain region having a dopant density greater than the drain drift region;
a field relief dielectric layer over the drain drift region, the field relief dielectric layer extending from the gate dielectric layer toward the drain region and having a thickness greater than the gate dielectric layer; and
a field plate located over the field relief dielectric layer and between the gate electrode and the drain region, wherein a position and a lateral width of the field plate are determined by:
adjusting a device model of the drain extended transistor based on simulated performance of the drain extended transistor using the device model.

17. The semiconductor device of claim 16, wherein the device model includes a drain-to-field plate capacitance of the drain extended transistor.

18. The semiconductor device of claim 17, wherein the drain-to-field plate capacitance of the device model varies in a non-linear fashion with one of a drain voltage of the drain extended transistor and a source voltage of the drain extended transistor.

19. The semiconductor device of claim 16, wherein the device model includes a drain-to-field plate resistance of the drain extended transistor.

20. The semiconductor device of claim 19, wherein the drain-to-field plate resistance of the device model varies in a non-linear fashion with a voltage applied to the field plate.
